(19) United States
(12) Patent Application Publication
(10) Pub. No.: US 2009/0116667 A1
(43) Pub. Date: May 7, 2009

(54) Method and Apparatus for Volume Adjustment

(75) Inventors: Yung-Da Lin, Chung Ho City (TW); Wei-Che Chang, Chung Ho City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AVERMEDIA TECHNOLOGIES, INC., Chung Ho City (TW)

(21) Appl. No.: 11/955,661

(22) Filed: Dec. 13, 2007

(30) Foreign Application Priority Data
Nov. 1, 2007 (TW) 96141246

(51) Int. Cl. H03G 3/00

(52) U.S. Cl. 381/107

(57) ABSTRACT

A method and an apparatus for adjusting volume are provided. A determining module receives a sound input signal, wherein the sound input signal is connected to a plurality of sound input sources and corresponds to one of the said sound input sources, the determining module further determines the corresponding sound input source of the sound input signal is different; a storing module stores a plurality of sound output records; a first calculating module calculates a sound output signal according to the sound input signal and the sound output records.

### RELATED APPLICATIONS

The present application is based on, and claims priority from, Taiwan Application Serial Number 96141246, filed on Nov. 1, 2007, the disclosure of which is hereby incorporated by reference herein in its entirety.

### BACKGROUND

1. Field of Invention

The present invention relates to a method and an apparatus for volume adjustment. More particularly, the present invention relates to a method and an apparatus that calculates a sound input signal and sound output record to adjust the volume.

2. Description of Related Art

Electronic entertainment devices have become more important due to an increase in leisure time of people. Multimedia entertainment in particular has become more popular since the quality of various media formats such as DVD, MP3, SACD have greatly improved.

Thus, a sound output device may be connected to various sound input sources. For example, a speaker used in a computer may receive different sound input sources from DVD players, MP3 players, CD players, and microphones and the sound effects from application software, etc. The volume of these different sound input sources may differ because the volume levels from the sources are substantially different or the volume settings of these players are different. A sudden difference in volume may occur when different sound input sources are chosen. If there is only a small difference between the volumes of two sequential audio input devices, listeners may only feel a little uncomfortable. However, if there is a large difference between the volumes of two sequential audio input devices, listeners may feel uncomfortable be irritated by the inconvenience.

Accordingly, what is needed is a method and an apparatus for automatic volume adjustment to overcome the above issues. The present invention addresses such a need.

### SUMMARY

The invention provides a method for volume adjustment comprising the steps of receiving a sound input signal, wherein the sound input signal is connected to a plurality of sound input sources and corresponds to one of the said sound input sources; determining the corresponding sound input source of the sound input signal is different; reading a plurality of sound output records; and calculating a sound output signal according to the sound input signal and the sound output records.

Another object of the present invention is to provide an apparatus to adjust the volume comprising: a determining module for receiving a sound input signal, wherein the sound input signal is connected to a plurality of sound input sources and corresponds to one of the said sound input sources, the determining module further determines the corresponding sound input source of the sound input signal is different; a storing module for storing a plurality of sound output records; and a first calculating module for calculating a sound output signal according to the sound input signal and the sound output records.

The present invention calculates the sound input signal and the sound output records to produce an appropriate sound output signal such that the volume output level won't differ significantly when sound input source is switched, and won't cause any disturbance to the listener.

These and other features, aspects, and advantages of the present invention will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a block diagram of the first embodiment of the present invention;

FIG. 2 is a block diagram of an apparatus for volume adjustment of the first embodiment of the present invention; and

FIG. 3 is a flow chart of a method for volume adjustment of the second embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

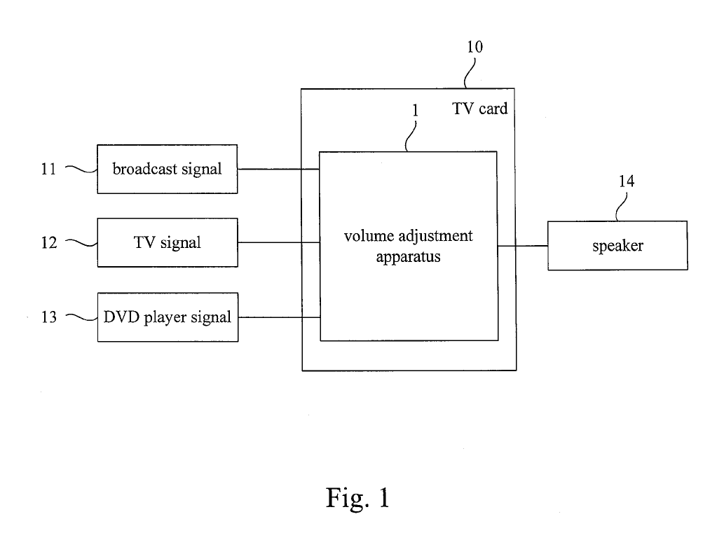

Please refer to FIG. 1, a block diagram of a first embodiment of the present invention. A volume adjustment apparatus 1 is placed in a TV card 10. The volume adjustment apparatus 1 can receive a sound input signal from one of three sound input sources: broadcast signals 11, TV signals 12 and DVD player signals 13. After the adjustment of the volume adjustment apparatus 1, a sound output signal is sent to a speaker 14. The volume adjustment apparatus 1 can receive different sounds from different types of sound input sources and can send the sound output signal to other apparatus that can generate output sounds.

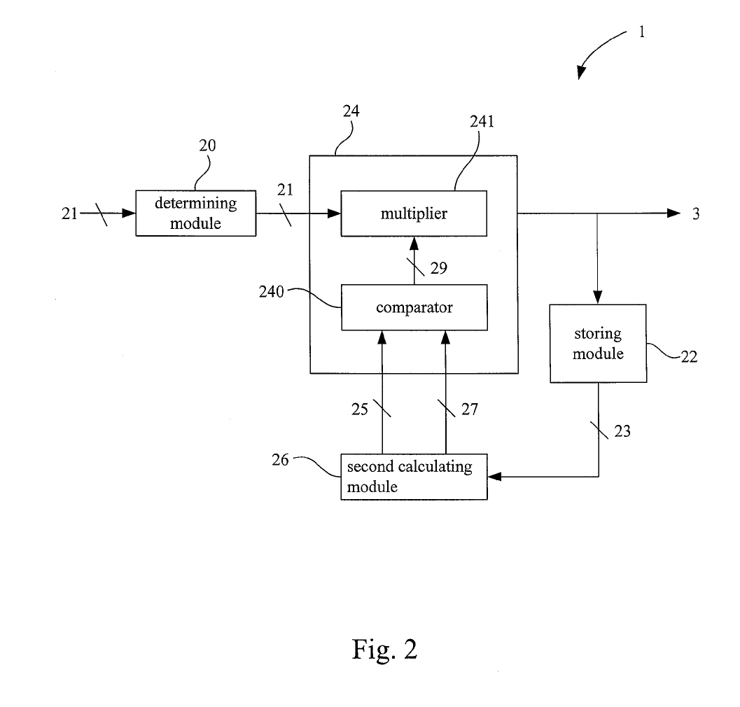

A more detailed block diagram of the volume adjustment apparatus is as shown in FIG. 2. The volume adjustment device 1 comprises a determining module 20, a storing module 22, a first calculating module 24 and a second calculating module 26. The determining module 20 receives a sound input signal 21, wherein the sound input signal 21 is connected to a plurality of sound input sources described above and corresponds to one of the said sound input sources, the determining module 20 further determines whether the corresponding sound input source of the sound input signal is different; the storing module 22 stores a plurality of sound output records 23, wherein the sound output records 23 in the form of Y[0], Y[1], . . . , Y[n] store the sound output records of a certain interval of time. The second calculating module 26 calculates a first average volume 25 according to Y[0] to Y[n] of the sound output records 23, and further calculates a second average volume 27 according to Y[0] to Y[n−1] of the sound output records 23. The first and the second average volume can be formularize as follow:

average volume=10 log(Σᵢ₌₁ⁿY[i]²)

The first calculating module 24 comprises a comparator 240 and a multiplier 241. The comparator 240 receives the first average volume 25 and the second average volume 27 and calculates an offset value 29 according to the first average volume 25 and the second average volume 27; then the multiplier 241 multiplies the offset value 29 and sound input signal 21 to generate a sound output signal 3, wherein the best function for the generation of the offset value 29 and sound output signal 3 can be derived from experimentations to make the difference between the sound output signal 3 and the sound input signal 21 be in a reasonable range. People skilled in this field can easily understand how to find the best function. Thus the detail is not described here.

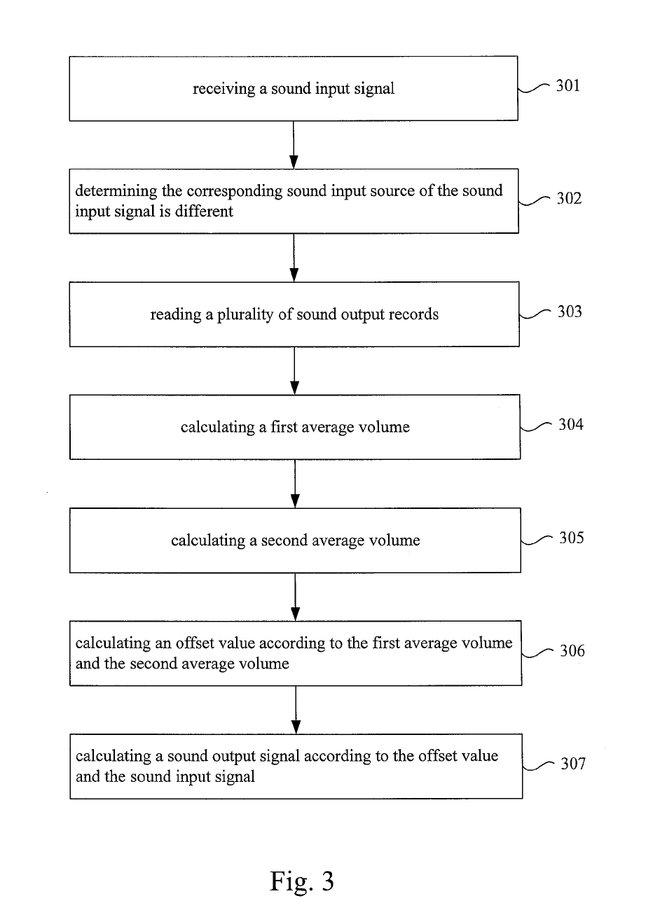

The second embodiment of the present invention is a method for volume adjustment, wherein the method is adapted in an apparatus for volume adjustment as described in the first embodiment. Please refer to FIG. 3. Step 301 is executed first, the determining module 20 receives a sound input signal, wherein the sound input signal is connected to a plurality of sound input sources and corresponds to one of the said sound input sources. Step 302 is executed in which the determining module 20 determines the corresponding sound input source of the sound input signal is different; then in step 303 a plurality of sound output records is read. In step 304 the second calculating module 26 calculates a first average volume, then in step 305 the second calculating module 26 calculates the second average volume according to the sound output records. Next, in step 306 the comparator 204 of the first calculating module 24 calculates an offset value according to the first average volume and the second average volume. Then, in step 307 the multiplier 241 calculates a sound output signal according to the offset value and the sound input signal.

In addition to the steps described above, the second embodiment can also execute the operations and functions described in the first embodiment. People skilled in this field can directly understand how the second embodiment executes these operations and functions based on the first embodiment described above. Thus the detail is not described here.

Accordingly, the present invention calculates sound input signal and sound output records to produce an appropriate sound output signal such that the volume won't have huge difference during the switching of the sound input source, and won't cause disturbance to the user.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A volume adjustment method comprising the steps of:
receiving a sound input signal, wherein the sound input signal is connected to a plurality of sound input sources and corresponds to one of the said sound input sources
determining the corresponding sound input source of the sound input signal is different;
reading a plurality of sound output records; and
calculating a sound output signal according to the sound input signal and the sound output records.

2. The volume adjustment method of claim 1 wherein the step of calculating the sound output signal further comprises the steps of:
calculating a first average volume according to the sound output records;
calculating a second average volume according to the sound output records;
calculating an offset value according to the first average volume and the second average volume; and
calculating the sound output signal according to the offset value and the sound input signal.

3. The volume adjustment method of claim 1 wherein the volume adjustment method is adapted in a volume adjustment apparatus in a TV card.

4. An apparatus for volume adjustment comprises:
a determining module for receiving a sound input signal, wherein the sound input signal is connected to a plurality of sound input sources and corresponds to one of the said sound input sources, the determining module further determines the corresponding sound input source of the sound input signal is different;
a storing module for storing a plurality of sound output records; and
a first calculating module for calculating a sound output signal according to the sound input signal and the sound output records.

5. The apparatus of claim 4 further comprising a second calculating module for calculating a first average volume and a second average volume according to the sound output records.

6. The apparatus of claim 5, wherein the first calculating module comprises
a comparator for calculating an offset value according to the first and the second average volume; and
a multiplier for calculating the sound out put signal according to the offset value and the sound input signal.

7. The apparatus of claim 4, wherein the apparatus is adapted in a TV card.
